(19) United States
(12) Patent Application Publication
(10) Pub. No.: US 2009/0173567 A1
(43) Pub. Date: Jul. 9, 2009

(54) Folded triangular sidewall ducted ports for loudspeaker enclosure

(76) Inventor: Enrique M. Stiles, Imperial Beach, CA (US)

Correspondence Address: RICHARD C. CALDERWOOD, 2775 NW 126TH AVE, PORTLAND, OR, 97229-8381, US

(21) Appl. No.: 12/006,896

(22) Filed: Jan. 7, 2008

(51) Int. Cl. H05K 5/00; A47B 81/06

(52) U.S. Cl. 181/148; 181/199

(57) ABSTRACT

A loudspeaker enclosure having a folded duct formed by an adjoining pair of the enclosure's panels and a pair of diagonally mounted internal panels. For example, at a lower left corner of the enclosure, a triangular first portion of the folded duct extends inward from a triangular hole in the front panel toward the back panel and is formed by the left panel, the bottom panel, and a first internal duct panel; and a trapezoidal second portion of the folded duct extends in the opposite direction and is formed by the left panel, the bottom panel, the first internal duct panel, and a second internal duct panel. The first internal duct panel is coupled to the front panel but ends short of the back panel to form the fold connecting the first and second portions of the folded duct, and the second internal duct panel is coupled to the back panel but ends short of the front panel to connect the folded duct with the enclosed air volume of the enclosure. The loudspeaker enclosure may be configured as a conventional vented enclosure, or as a fourth or sixth order bandpass enclosure.

### BACKGROUND OF THE INVENTION

1. Technical Field of the Invention

This invention relates generally to loudspeaker enclosures, and more specifically to ported enclosures opposed to sealed enclosures, and yet more specifically to enclosures having triangular ducted ports which at least partially utilize existing enclosure walls to create the ducts.

2. Background Art

Throughout this disclosure, for ease of illustration, loudspeakers will be discussed as though having only a single transducer. Those skilled in the art will readily appreciate that the principles of this invention are, however, not limited to that case and that this invention may be practiced in loudspeakers having multiple transducers of the same size or type or of varying sizes or types. And, for ease of illustration, loudspeaker enclosures will be discussed as though they were in the three-dimensional shape of a rectangular prism, although those of skill in the art will readily appreciate that the invention may be practiced with other shapes of loudspeaker enclosures as well.

Loudspeaker enclosures may generally be categorized as either the sealed enclosure type, the ported type, or the bandpass type. A sealed enclosure typically has six rectangular panels coupled together to form a box enclosing a volume of air. One of the panels has a hole cut through it, into which an electromagnetic transducer (“speaker driver”) is mounted. The panels and the transducer together form a sealed enclosure, such that when the transducer's diaphragm is pulled inward by the transducer's motor, the air inside the enclosure is pressurized, and when the diaphragm is pushed outward by the motor, the air inside the enclosure is rarified. A sealed enclosure may have small, incidental air leaks, but these are undesirable and the designer and manufacturer should avoid them, because they cause noise and can somewhat alter the tuning characteristics of the enclosure.

A ported enclosure, sometimes called a vented enclosure, is constructed in that same manner, with one modification. Another hole is cut through one of the panels, typically the front panel, and a duct of a predetermined cross-sectional area and length is connected to the panel so as to extend from the hole inward into the enclosed air space. The duct alters the tuning characteristics of the enclosure in a manner determined by factors including the cross-sectional area and length of the duct, the volume of the enclosed air within the enclosure, and so forth.

One undesirable characteristic of conventional ducts is that the port hole and the transducer hole cannot occupy the same area or overlapping areas on the same panel, in other words, the front panel must be large enough to accommodate both. Both holes being circular does not lend to achieving a good packing factor. Another is that the duct and the transducer cannot occupy the same space within the enclosure. In many applications, it is desirable to make the front panel as small as possible, such that its size is limited only by the dimensions of the transducer. With a circular transducer and a square front panel, this leaves only four very small, generally triangular areas of the front panel through which a port could be cut. In many cases, these areas are simply too small for a circular duct to provide the minimum required port cross-sectional area to avoid port wind noise during high SPL operation. Some enclosures have included more than one port, but it is known that it is problematic to achieve the same results with plural ducts that can otherwise be achieved with a single duct, in part because the interior duct wall surface area to duct cross-sectional area ratio is higher with plural ducts than with a single, larger cross-sectional area duct.

In some enclosures, the desired port tuning characteristics require a duct whose length cannot fit within the internal dimensions of the enclosure. A few loudspeakers have addressed this problem by using “folded” or “bent” ducts. In some cases, the duct has been bent into an L shape. In some cases, the duct has been folded into a U shape.

And in one highly unusual loudspeaker enclosure conceived by this inventor while working at Pioneer designing a premium upgrade audio system for the Pontiac Aztec, the duct was formed as a pair of concentric tubes. In this enclosure, the smaller diameter tube was coupled to the panel hole, and the larger diameter tube was coupled to the inner surface of the opposite panel. Both ends of the smaller tube were open, but only one end of the larger tube was open—the other end of the larger tube was sealed against the inner surface of the opposite panel. The standing air column within the duct had a shape approximately like the shape of a nearly closed umbrella; from the listening space, the air column extending through the exposed port hole, down the length of the inside of the smaller duct, then folded radially outward in all directions as the far end of the smaller tube came close to but did not touch the closed end of the larger tube, then extended back in the opposite direction in the shape of an annulus or a ring, until it met the main body of the enclosed air volume within the enclosure where the larger tube ended short of the front panel.

Another issue, with both ported and sealed enclosures, is that it is generally desirable that the panels be as rigid as possible. If the panels flex during operation of the loudspeaker, they themselves act as diaphragms or radiators, reducing the quality of the sound produced by the loudspeaker. This is especially true of the panel where the transducer is mounted.

Yet another issue, with both ported and sealed enclosures, is that it is desirable to reduce or eliminate standing waves within the enclosure. Standing waves occur most readily in an enclosure in which opposing internal surfaces are parallel. Pressure waves in effect “echo” back and forth between the parallel surfaces, and cause undesirable effects on the sound produced by the diaphragm.

Still another issue with ported enclosures is the additional manufacturing cost and increased parts count caused by the duct components, which typically include one or more pipes, one or more flared ends, and one or more elbow joints.

What is desirable, then, is an improvement in ported loudspeaker enclosures, which makes better use of front panel surface area than a circular duct can, and which provides the length advantage of a folded duct in a limited dimension enclosure, and which optionally also improves enclosure rigidity and helps reduce standing waves, and potentially lowers cost.

### BRIEF DESCRIPTION OF THE DRAWINGS

FIG. 1 shows one embodiment of a loudspeaker enclosure according to the principles of this invention, in front perspective view.

FIG. 2 shows the loudspeaker enclosure of FIG. 1 in cutaway view from a different angle.

FIG. 3 shows the loudspeaker enclosure of FIG. 1 in an exploded and cutaway view.

FIG. 4 shows another embodiment of the invention implemented in a fourth order bandpass enclosure.

FIG. 5 shows another embodiment of the invention implemented in a sixth order bandpass enclosure with a passive radiator.

FIG. 6 shows another embodiment of the invention implemented in a sixth order bandpass enclosure with a folded triangular port venting the first chamber and a symmetrically loaded triangular port venting the second chamber.

FIG. 7 shows a top view and a cross-section of the loudspeaker enclosure of FIG. 1.

FIG. 8 shows a loudspeaker enclosure according to another embodiment of this invention, in which the second and third inner duct panels are mounted such that the second and third portions of the duct also have triangular cross-sectional shapes.

FIG. 9 shows a loudspeaker enclosure according to yet another embodiment of this invention, in which the final inner duct panel is coupled to a different pair of panels to create its portion of the duct.

FIG. 10 shows a front perspective view of another embodiment of an enclosure having a dual-folded duct, with the front and back panels removed for illustration purposes.

FIG. 11 shows a rear perspective view of the enclosure of FIG. 10.

FIG. 12 shows a bottom perspective view of the enclosure of FIG. 10, with the front and back panels in place but the bottom panel removed for illustration purposes.

### DETAILED DESCRIPTION

The invention will be understood more fully from the detailed description given below and from the accompanying drawings of embodiments of the invention which, however, should not be taken to limit the invention to the specific embodiments described, but are for explanation and understanding only.

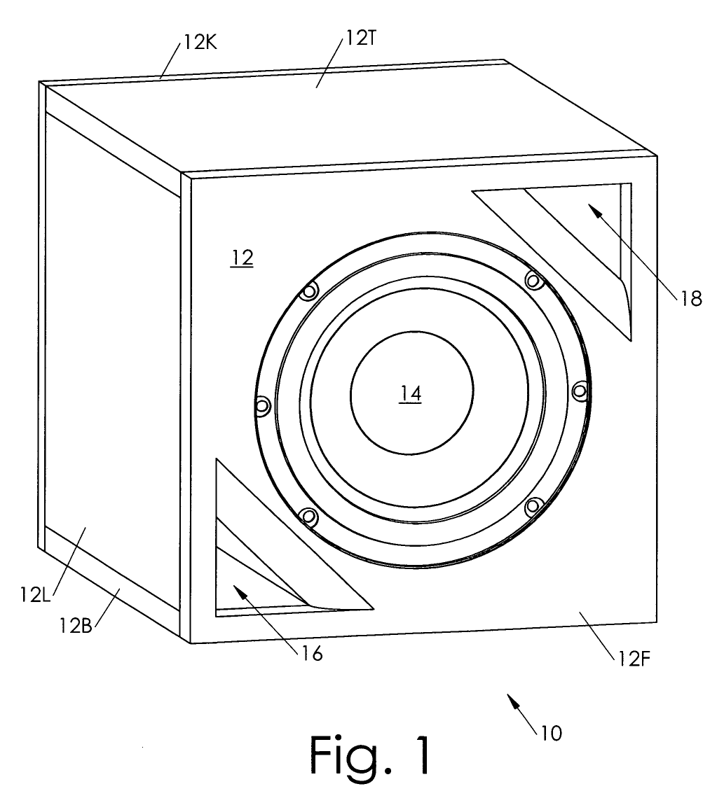

FIG. 1 illustrates a loudspeaker 10 according to one embodiment of this invention. The loudspeaker includes an enclosure 12 which, in one embodiment, may be formed of six square or rectangular panels. The panels may include a front panel 12F, a back panel 12K, a left panel 12L, a right panel 12R (mostly not visible from this angle), a top panel 12T, and a bottom panel 12B. The loudspeaker includes an electromagnetic transducer 14 which is coupled to and extends through a hole through the front panel.

The enclosure includes one or more folded triangular ducted ports, each of which extends through one of the panels. In the embodiment shown, there are two ports 16 and 18, and they both extend through the front panel. The generally triangular shape of the ports enables them to make excellent use of the generally triangular shape of the portions of the front panel in the corners of the front panel beyond the perimeter of the generally circular transducer.

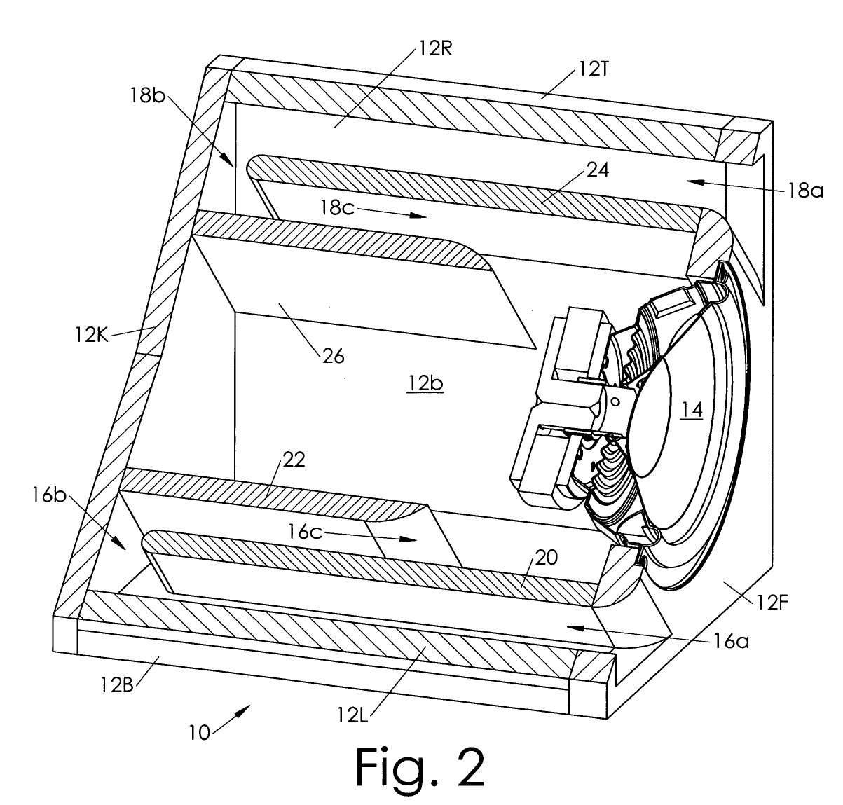

FIG. 2 illustrates the loudspeaker 10 in cutaway view, showing details of the improved duct structure of one embodiment of this invention. Each folded duct is formed along a corner where two of the enclosure panels meet. The duct 16 in the lower left corner of the front panel 12F is formed by first and second internal duct panels 20 and 22 as well as the left panel 12L, the back panel 12K, and the bottom panel 12B. The duct 18 in the upper right corner of the front panel is formed by third and fourth internal duct panels 24 and 26 as well as the right panel 12R, the rear panel 12K, and the top panel 12T.

The standing air column in the folded port 16 includes three general portions. From the external listening space, it extends through the generally triangular hole in the front panel, then along a first primary portion 16a having a generally triangular cross-sectional shape bounded by the inner surface of the left panel, the inner surface of the bottom panel, and a first surface of the first internal duct panel 20. The first internal duct panel is coupled to the left panel, bottom panel, and front panel, but ends short of the back panel. An intermediate portion 16b of the standing air column turns around the rear end of the first internal duct panel. And a second primary portion 16c of the standing air column extends forward to the near end of the second internal duct panel 22. This second portion of the standing air column has a generally trapezoidal cross-sectional shape bounded by a second surface of the first internal duct panel, a first surface of the second internal duct panel, the inner surface of the left panel, and the inner surface of the bottom panel. The intermediate portion joins the first and second primary portions.

Similarly, the standing air column in the folded port 18 includes three portions 18a, 18b, and 18c, formed by the top panel, right panel, back panel, and third and fourth internal duct panels 24, 26.

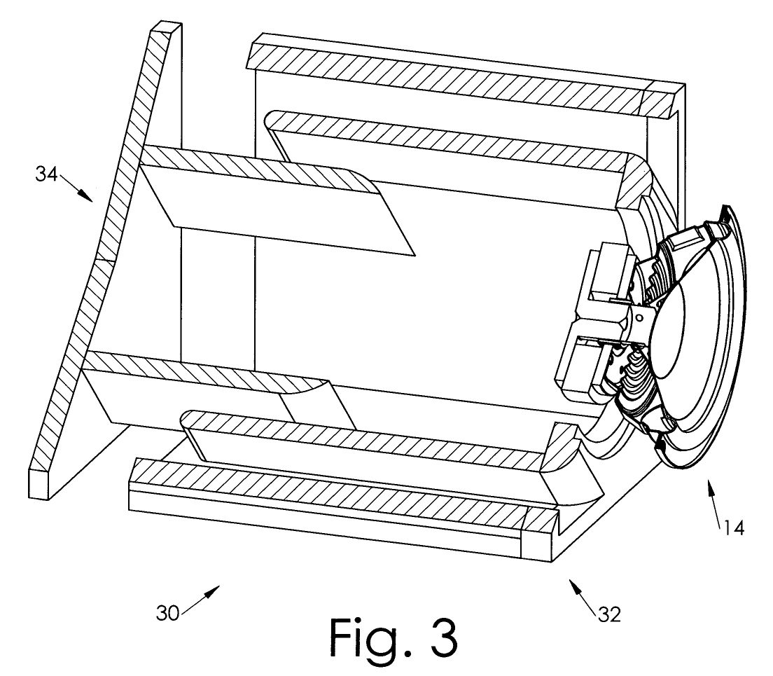

FIG. 3 illustrates the loudspeaker in an exploded cutaway view 30, illustrating one optional manufacturing configuration in which the front panel, the four side panels, and the first and third internal duct panels are formed as a first monolithic unit, and the back panel and the second and fourth internal duct panels are formed as a second monolithic unit. These two units are configured such that they can be slid into assembly and fastened together, forming the enclosure of FIGS. 1 and 2. Any suitable manufacturing technique and material may be utilized, such as, by way of example only, injection molded plastic, cast metal, molded epoxy, and so forth.

In another such embodiment, the front and/or back panels may be formed separately from a central monolithic piece that includes the four side panels and the four internal duct panels; in such an embodiment, the central component can be cut from e.g. a metal extrusion and then machined to achieve the appropriate duct wall lengths for the first and third, and second and fourth internal duct panels.

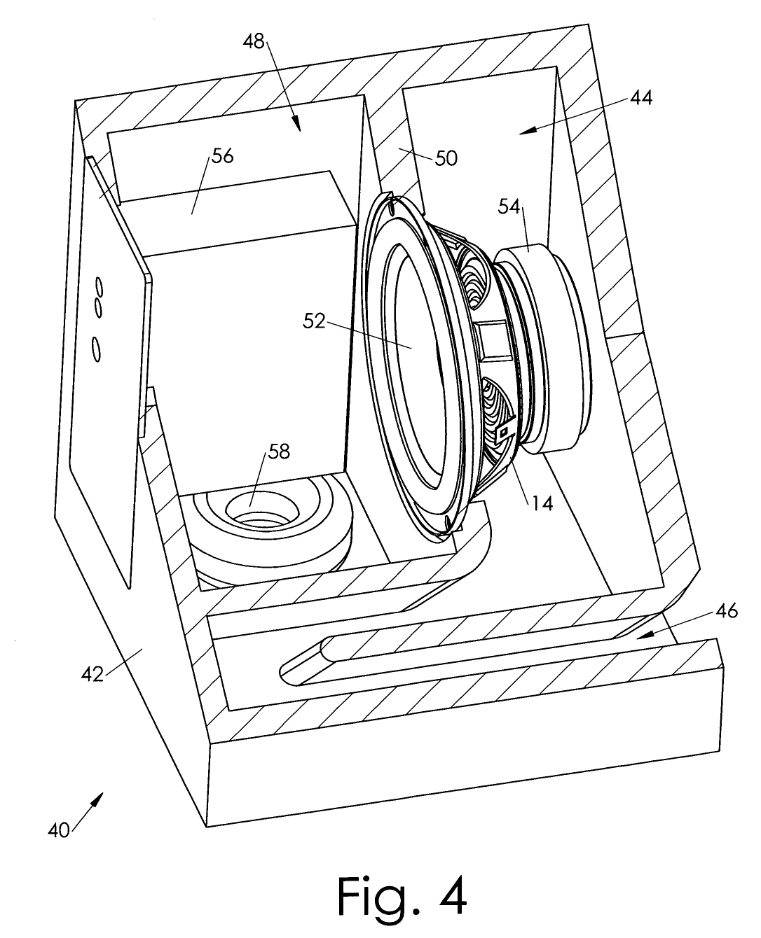

FIG. 4 illustrates a loudspeaker 40 having a fourth order bandpass enclosure 42 according to another embodiment of this invention. The enclosure has a first chamber 44 which is vented by a folded triangular ducted port 46, and a sealed second chamber 48.

A transducer 14 is coupled at a hole through an internal panel 50 of the enclosure such that a first surface (not visible) of its diaphragm is in the first chamber, and a second surface 52 of its diaphragm is in the second chamber. In the embodiment shown, the motor 54 of the transducer is disposed within the first chamber; in another embodiment the transducer could be reversed such that its motor is disposed within the second chamber. Having the motor in the first chamber may provide some small amount of cooling of the motor by air flow through the ducted port.

Optionally, the loudspeaker may further include an amplifier 56 and a torroidal transformer 58 coupled to drive the transducer. In the embodiment shown, these may be disposed within the second chamber of the enclosure. It may be advantageous to not have the transducer motor and the amplifier in the same chamber, especially the sealed second chamber, to avoid overheating.

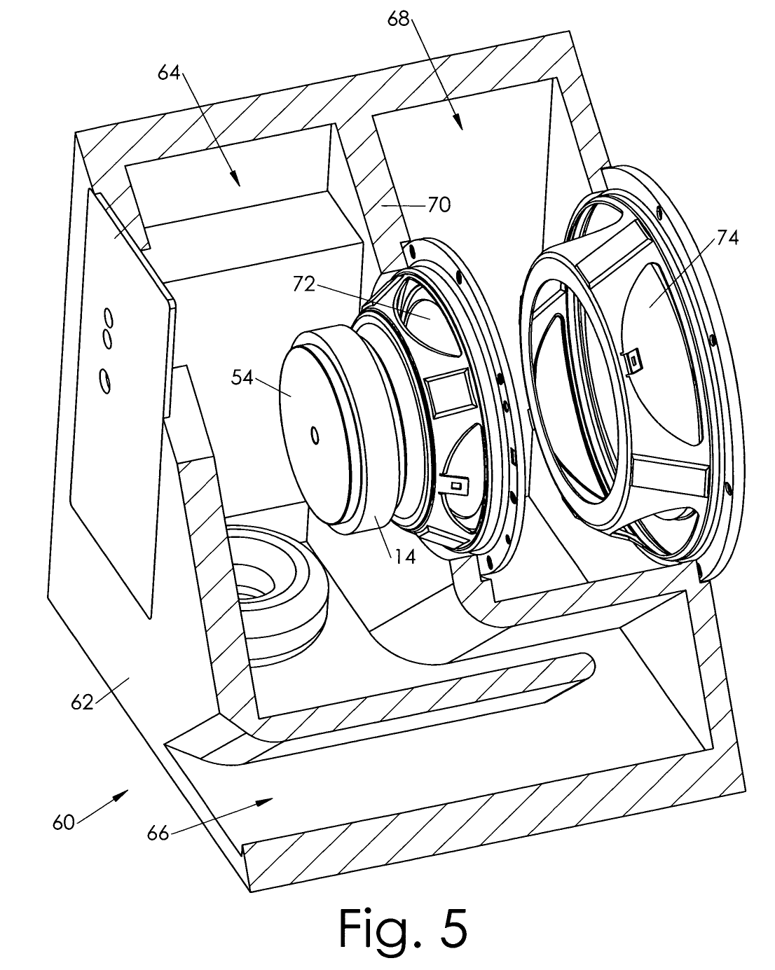

FIG. 5 illustrates a loudspeaker 60 having a sixth order bandpass enclosure 62 according to yet another embodiment of this invention. The enclosure has a first chamber 64 which is vented by a folded triangular ducted port 66, and a second chamber 68.

A transducer 14 is coupled at a hole through an internal panel 70 of the enclosure such that a first surface (not visible) of its diaphragm is in the second chamber, and a second surface 72 of its diaphragm is in the first chamber.

A passive radiator 74 is coupled at a hole through an exterior panel of the enclosure so as to have its back surface in the second chamber. Thus, sound pressure produced by the first (in this case front) surface of the transducer's diaphragm is coupled to the listening environment by the passive radiator, and sound pressure produced by the second (in this case rear) surface of the transducer's diaphragm is coupled to the listening environment by the folded triangular ducted port. The use of at least one passive radiator in a bandpass enclosure is particularly advantageous because it can serve a second purpose as an access panel to the internal active driver, by simply using a passive radiator that is sufficiently larger than the active driver.

In the embodiment shown, the ducted port is folded once (into a U shape), with the result that the sound from the ducted port and the sound from the passive radiator are produced from opposite sides of the loudspeaker. In another embodiment, the ducted port could be folded twice (into a Z shape), and the sound from both the ducted port and the passive radiator would be produced from the same side of the loudspeaker. In still other embodiments, the passive radiator could be mounted to a wall that is perpendicular to the port opening wall, such that the passive radiator or the port is side firing.

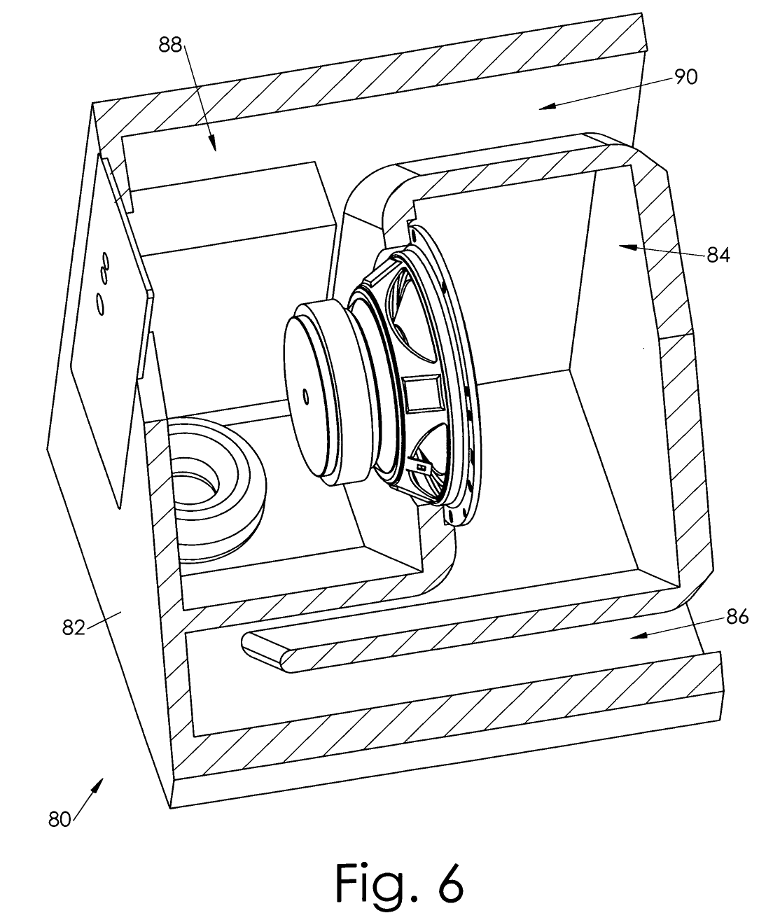

FIG. 6 illustrates a loudspeaker 80 having a sixth order bandpass enclosure 82 according to another embodiment of this invention. The enclosure has a first chamber 84 which is vented by a folded triangular ducted port 86, and a second chamber 88 which is vented by a symmetrically loaded triangular port 90. In the embodiment shown, the triangular port 90 is not folded and exits the enclosure on the same side as the folded triangular ducted port 86; in another embodiment, both are folded, and they may exit on opposite sides of the enclosure, the same side of the enclosure, or even adjacent sides of the enclosure.

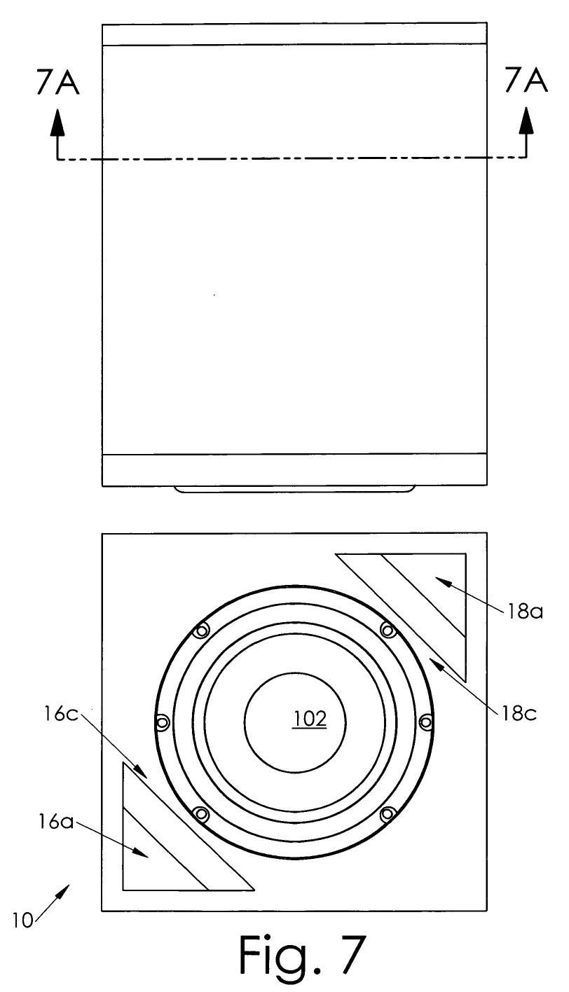

FIG. 7 illustrates the loudspeaker 10 of FIG. 1 in a top view and in a cross-sectioned front view taken as indicated at 7A. This front view provides an even clearer visualization of the cross-sectional shapes of the respective portions of the ducted port. The initial portion 16a of the ducted port has a triangular cross-sectional shape, as it is formed by the bottom panel, the left panel, and the first interior duct panel. The final portion 16c of the ducted port has a trapezoidal (or other four-sided) cross-sectional shape, as it is formed by the bottom panel, the left panel and the first and second interior duct panels. If the ducted port had a Z shape, there could be another trapezoidal portion shaped by the bottom panel, the left panel, and the second and a third interior duct panel.

The optional second folded triangular ducted port 18 has portions 18a and 18c similarly shaped in the embodiment shown.

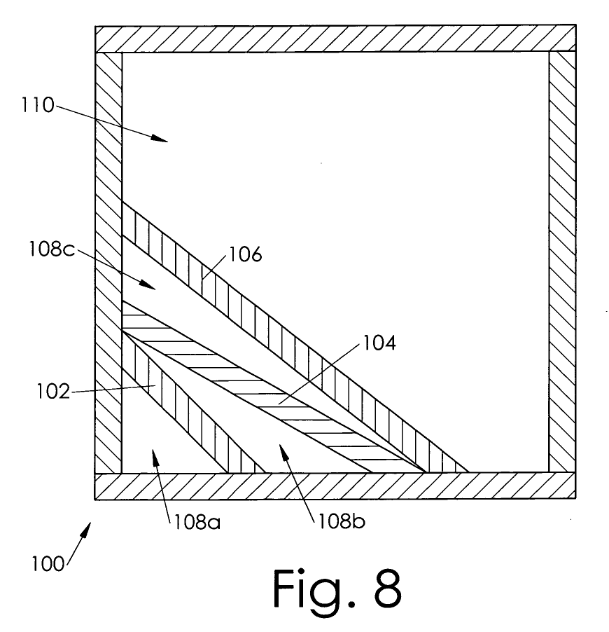

FIG. 8 illustrates a loudspeaker enclosure 100 in cutaway front view similar to the view of FIG. 7. The enclosure has a first inner duct panel 102 which is coupled as described above. A second inner duct panel 104 is coupled at an angle such that it forms a triangular cross-section duct segment with the first inner duct panel and the bottom exterior panel. This advantageously moves the second inner duct panel to a lower position, leaving more clearance above it for the transducer (not seen in this view). The cross-sectional areas of the first portion 108a of the duct and the second portion 108b of the duct may be substantially the same, although their shapes may be significantly different, as shown.

An optional third inner duct panel 106 is mounted as shown, and forms a third portion 108c of a Z-shaped duct as described above. Alternatively, the third inner duct panel could be slid downward to mate with the second inner duct panel at the left corner, just as the first and second inner duct panels mate, which could also allow more clearance for a woofer above.

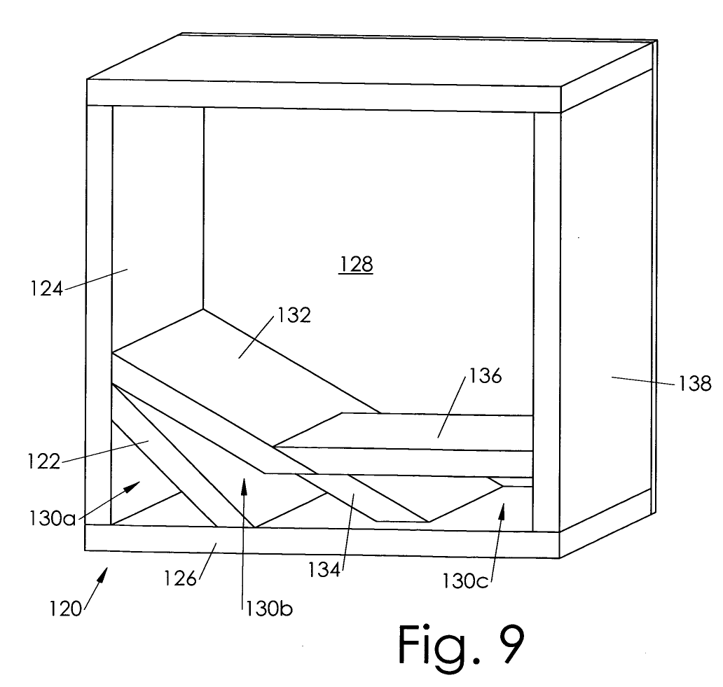

FIG. 9 illustrates a loudspeaker enclosure 120 according to another embodiment of this invention. A first inner duct panel 122 is coupled to the left panel 124 and the bottom panel 126, and also to the front panel which has been removed for the purpose of providing visibility into the inner portions of the enclosure. The first inner duct panel ends short of the back panel 128. The first inner duct panel, left panel, and bottom panel form a triangular first portion 130a of a folded duct.

A second inner duct panel 132 is coupled to the left panel and the bottom panel, and may advantageously be slid down the left panel until it meets the first inner duct panel as shown, to form a second triangular portion 130b of the folded duct. In the case of a U-shaped folded duct, the second inner duct panel would end short of the front panel (not shown). In the case of a Z-shaped double-folded duct as shown, the second inner duct panel extends to the front panel except for a portion 134 which ends short of the front panel. In this case, a third inner duct panel 136 is coupled to the second inner duct panel and to another panel—in the instance illustrated, the right panel 138—to form a third portion 130c of the folded duct and does not extend all the way to the back panel.

In the case of the Z-shaped duct, coupling the third inner duct panel to the right panel provides some stiffening of the right panel.

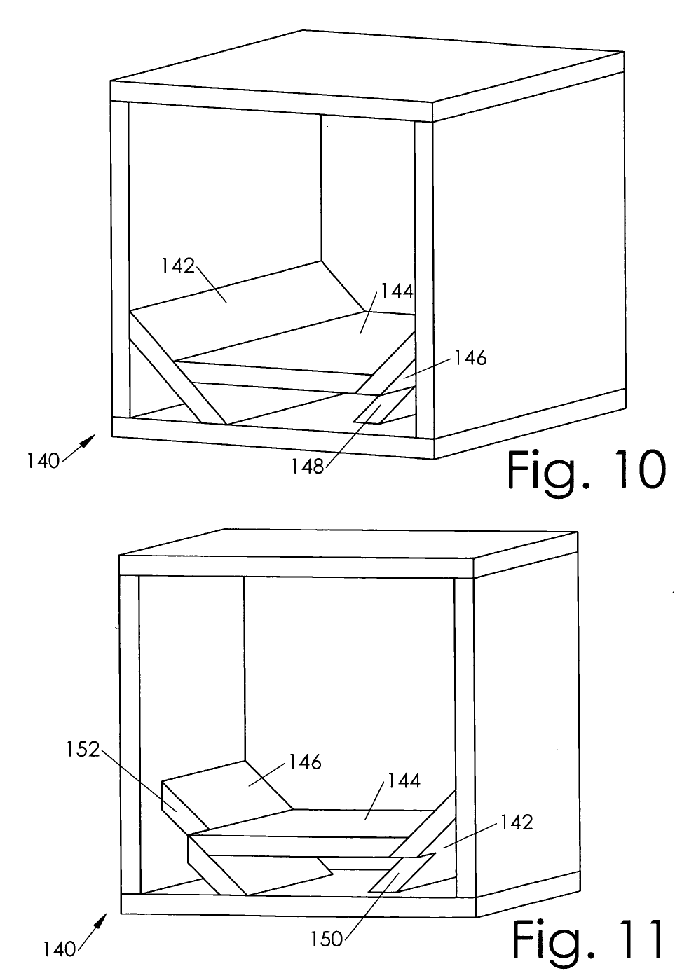

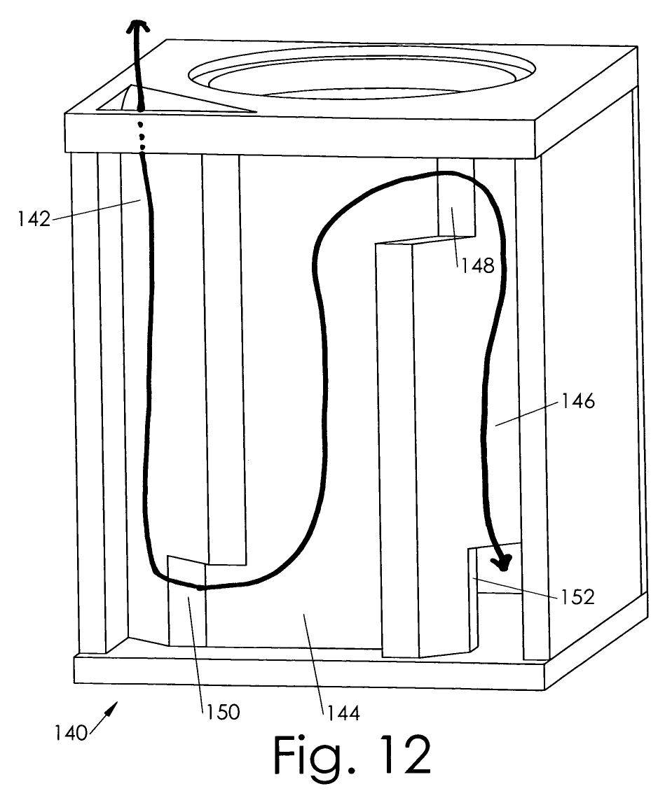

FIGS. 10-12 illustrate a loudspeaker enclosure 140 according to yet another embodiment of this invention. In this embodiment, the enclosure has a dual-folded duct. A first portion of the folded duct is formed by the left and bottom panels and a first internal duct panel 142 which mates with the front panel and partially mates with the back panel except at a cutout 150.

A second portion of the folded duct is formed by the first internal duct panel, the bottom panel, a second internal duct panel 144, and a third internal duct panel 146. The second internal duct panel is coupled to the first and third internal duct panels and to the front and back panels.

A third portion of the folded duct is formed by the third internal port panel, the bottom panel, and the right panel. The third internal port panel mates with the front panel except at a cutout 148, and with the back panel except at a cutout 152.

The cutout 150 connects the triangular first portion of the folded duct to the trapezoidal second portion of the duct. The cutout 148 couples the trapezoidal second portion of the duct to the triangular third portion of the duct. The cutout 152 couples the triangular third portion of the duct to the enclosed air volume within the loudspeaker enclosure. The port hole through the front panel vents the triangular first portion of the folded duct to the listening environment.

### CONCLUSION

The first and second internal duct panels are rigidly coupled to the left and bottom panels, and the third and fourth internal duct panels are rigidly coupled to the right and top panels, which may provide significant gusset type bracing which stiffens the side panels, reducing their tendency to vibrate and distort the sound produced by the loudspeaker.

The angles of the second (upper) surface of the first internal duct panel and of the second (upper) surface of the second internal duct panel are not parallel to the inner surface of the right panel nor to the inner surface of the top panel, which they generally face. This will help reduce standing waves between the left and right panels, and between the top and bottom panels.

For convenience, the first and second internal duct panels are shown as being substantially parallel, but this is not a necessary limitation of all embodiments of the invention. In other words, the third portion of the standing air column does not necessarily have a normal trapezoidal cross-sectional shape. In some embodiments, the internal duct panels are formed of flat panel material, but other shapes may be used in other embodiments. And for convenience, the internal duct panels are shown as extending generally parallel to the line formed by the intersection of the left and bottom panels, but in other embodiments they could be coupled at other angles within the enclosure in order to achieve gradually changing cross-sectional area. And for convenience, the first and second internal duct panels are shown as being coupled to the enclosure at approximately a 45° angle, so as to give the outside port hole a substantially isosceles triangle shape, but in other embodiments, they could be coupled at other angles.

In the embodiment shown, a second such duct is formed in the opposite corner of the enclosure. In other embodiments, a second duct could instead be formed in an adjacent corner such as the lower right corner. This may provide even greater reduction of standing waves, as it will tend to not only reduce the amount of the right panel's surface area that is exposed to the parallel left panel, but also to avoid standing waves between the respective ducts' internal duct panels themselves.

And in the embodiment shown, the ports all extend through either the front panel or the rear panel. In other embodiments they could extend through other panels such as side panels.

The left, right, top, and bottom panels of the enclosure may collectively be termed “side panels”. The side panels, front panel, and back panel may collectively be termed “exterior panels”. If the enclosure has four side panels, it will have a generally rectangular shape; if it has three side panels, it will have a generally triangular shape; and so forth. In some embodiments such as certain pyramid or wedge shaped enclosures, the rear panel may be omitted, or, more accurately, its function may be performed by one or more of the other panels having a suitable shape or angle. The panels may be distinct components glued etc. together, or two or more of them may be formed as a monolithic whole—in the extreme, the entire enclosure may be formed e.g. as a monolithic cast body.

The first and second internal duct panels need not necessarily be coupled to the same side panels, especially in the unusual case of e.g. an octagonal enclosure. And in the unusual cases of a circular enclosure or a spherical enclosure, the respective arc segments of the exterior panel(s) may be considered as though they were individual side panels, for purposes of understanding this invention.

In the embodiment shown, the folded duct includes only a single fold. That is, it forms a generally U shape. In other embodiments having one or more additional internal duct panels (in the same folded duct structure), a greater number of folds can be achieved, enabling the use of a duct length greater than twice the internal dimension of the enclosure. For example, if three internal duct panels are used, the folded duct has a generally Z shape, with three substantially parallel air column portions extending in alternating directions. However, it should be noted that with a front port opening, all of the “odd numbered” internal duct panels are coupled to the front panel, which limits the placement of the transducer if it is coupled to the front panel. The Z etc. embodiments may find best advantage with a port opening which is not on the same panel as the transducer, or when the depth of the enclosure is a key limiting factor.

When one component is said to be “adjacent” another component, it should not be interpreted to mean that there is absolutely nothing between the two components, only that they are in the order indicated.

The various features illustrated in the figures may be combined in many ways, and should not be interpreted as though limited to the specific embodiments in which they were explained and shown.

Those skilled in the art, having the benefit of this disclosure, will appreciate that many other variations from the foregoing description and drawings may be made within the scope of the present invention. Indeed, the invention is not limited to the details described above. Rather, it is the following claims including any amendments thereto that define the scope of the invention.

What is claimed is:

1. A loudspeaker enclosure comprising:
a plurality of exterior panels coupled together to enclose a volume of air, the exterior panels including a front panel and at least three side panels;
a first port hole extending through a first of the exterior panels [front panel]; and
a first folded duct including,
a first internal duct panel having a first end coupled to the first exterior panel, a first side coupled to a first side panel [right panel], and a second side coupled to a second side panel [top panel], so as to bound a first portion of an air column, and
a second internal duct panel having a first end coupled to at least one of the exterior panels [rear panel], a first side coupled to the first side panel, and a second side coupled to the second side panel, so as to bound a second portion of an air column;
whereby a first folded air column is formed within the first folded duct.

2. The loudspeaker enclosure of claim 1 further comprising:
an electroacoustic transducer coupled to the front panel.

3. The loudspeaker enclosure of claim 2 wherein:
the first exterior panel is the front panel.

4. The loudspeaker enclosure of claim 1 wherein:
the plurality of exterior panels includes a front panel, a right side panel, a left side panel, a top side panel, a bottom side panel, and a rear panel.

5. The loudspeaker enclosure of claim 1 further comprising:
a second folded duct disposed at a second port hole.

6. The loudspeaker enclosure of claim 5 wherein:
the first folded duct and the second folded duct extend through diagonally opposite corners of the first exterior panel.

7. The loudspeaker enclosure of claim 5 wherein:
the first folded duct and the second folded duct extend through adjacent corners of the first exterior panel.

8. The loudspeaker enclosure of claim 1 wherein:
the first interior duct panel is integrally formed with the first external panel; and
the second interior duct panel is integrally formed with a second external panel.

9. The loudspeaker enclosure of claim 1 wherein:
the first port hole has a substantially triangular shape.

10. The loudspeaker enclosure of claim 1 wherein:
the first and second internal duct panels are substantially parallel to one another.

11. The loudspeaker enclosure of claim 1 wherein:
the enclosure is configured as a fourth order bandpass enclosure.

12. The loudspeaker enclosure of claim 1 wherein:
the enclosure is configured as a sixth order bandpass enclosure.

13. The loudspeaker enclosure of claim 12 further comprising:
an electroacoustic transducer coupled to an internal panel separating a first chamber and a second chamber of the enclosure; and
a passive radiator coupling the second chamber to an exterior listening environment;
the enclosed volume of air being within the first chamber such that the first folded duct vents the first chamber.

14. The loudspeaker enclosure of claim 1 wherein:
a third internal duct panel having a first end coupled to at least one of the exterior panels [front panel], a first side coupled to the first side panel, and a second side coupled to the second side panel, so as to bound a third portion of the air column, whereby a dual-folded duct is formed.

15. A loudspeaker enclosure comprising:
six exterior panels coupled together to form an enclosure having a substantially rectangular prism shape, the six panels including a front panel, a rear panel, and side panels including a right panel, a left panel, a top panel, and a bottom panel, coupled together to enclose a volume of air; and
a first folded duct formed by,
a first internal duct panel substantially perpendicular to and coupled to the front panel, the first internal duct panel extending substantially parallel to a line formed at an intersection of two adjacent ones of the side panels and coupled to the two adjacent side panels, the first internal duct panel ending short of the rear panel,
a second internal duct panel substantially perpendicular to and coupled to the rear panel, the second internal duct panel extending substantially parallel to the line formed at the intersection of the two adjacent side panels and coupled to the two adjacent side panels, the second internal duct panel ending short of the front panel, and
a port hole extending through the front panel between the first internal duct panel and the two side panels.

16. The loudspeaker enclosure of claim 15 further comprising:
an electroacoustic transducer coupled at a hole extending through one of the exterior panels.

17. The loudspeaker enclosure of claim 16 wherein:
the exterior panel at which the electroacoustic transducer is coupled is the front panel.

18. The loudspeaker enclosure of claim 15 further comprising:
a second folded duct having a port hole extending through one of the exterior panels.

19. The loudspeaker enclosure of claim 18 wherein:
the exterior panel through which the port hole of the second folded duct extends is the front panel.

20. The loudspeaker enclosure of claim 19 wherein:
the first and second folded ducts are disposed at diagonally opposite corners of the front panel.

21. The loudspeaker enclosure of claim 19 wherein:
the first and second folded ducts are disposed at adjacent corners of the front panel.

22. The loudspeaker enclosure of claim 15 wherein:
the loudspeaker enclosure is configured as a bandpass enclosure.

23. A loudspeaker enclosure enclosing an air volume and comprising:
a plurality of external panels including at least a first [front] external panel, a second [left] external panel, a third [bottom] external panel, a fourth [back] external panel opposite the first external panel, and a fifth [right] external panel opposite the second external panel, wherein the first, second, and third external panels adjoin each other at a corner of the enclosure, and wherein the second and third external panels further adjoin each other along an edge of the enclosure extending from the corner;
the first external panel having a port hole extending there through adjacent the corner;
a first internal duct panel coupled diagonally to the second and third external panels so as to extend along the edge, and coupled to the first external panel adjacent the port hole so as to create a triangular first portion of a folded duct extending inward from the port hole from the first external panel toward the fourth external panel; and
a second internal duct panel coupled to one of the second external panel and the first internal duct panel, and coupled to the fourth external panel, and coupled to one of the third external panel and the fifth external panel, so as to create a second portion of the folded duct extending from the fourth external panel toward the first external panel;
wherein a first end of the folded duct is in contact with a listening environment through the port hole and a second end of the folded duct is in contact with the enclosed air volume.

24. The loudspeaker enclosure of claim 23 further comprising:
a third internal duct panel coupled to one of the second external panel and the second internal duct panel, and coupled to one of the third external panel and the fifth external panel, so as to create a third portion of the folded duct extending from the first external panel toward the fourth external panel.

25. The loudspeaker enclosure of claim 23 further comprising:
an electroacoustic transducer coupled to one of the external panels so as to have a first diaphragm surface in contact with a listening environment outside the enclosure and a second diaphragm surface in contact with the enclosed air volume.

26. The loudspeaker enclosure of claim 23 further comprising:
an internal panel dividing the enclosed air volume into a first chamber and a second chamber; and
an electroacoustic transducer coupled to the internal panel so as to have a first diaphragm surface in contact with the first chamber and a second diaphragm surface in contact with the second chamber.

27. The loudspeaker enclosure of claim 26 further comprising:
the folded duct coupling the first chamber to an external listening environment; and
a passive radiator coupling the second chamber to the external listening environment.

28. The loudspeaker enclosure of claim 26 further comprising:
the folded duct coupling the first chamber to an external listening environment; and
a port coupling the second chamber to the external listening environment.

29. The loudspeaker enclosure of claim 23 further comprising:
a sixth [top] external panel opposite the third external panel.

30. The loudspeaker enclosure of claim 23 wherein:
at least two of the panels are formed as a monolithic component.
